(19) United States
(12) Patent Application Publication
(10) Pub. No.: US 2019/0040185 A1
(43) Pub. Date: Feb. 7, 2019

(54) METHOD

(71) Applicants: Cambridge Display Technology Limited, Godmanchester (GB); Sumitomo Chemical Company Limited, Tokyo (JP)

(72) Inventors: Florence Bourcet, Godmanchester (GB); Stephen Wright, Godmanchester (GB); Jean-Benoit Giguere, Godmanchester (GB)

(73) Assignees: Cambridge Display Technology Limited, Godmanchester (GB); Sumitomo Chemical Company Limited, Tokyo (JP)

(21) Appl. No.: 15/999,304

(22) PCT Filed: Feb. 16, 2017
(86) PCT No.: PCT/GB2017/050401

§ 371 Date: Aug. 17, 2018

(30) Foreign Application Priority Data
Feb. 19, 2016 (GB) 1602927.4

(51) Int. Cl. C08G 61/02; H01L 51/00; H01L 51/50

(52) U.S. Cl. CPC C08G 61/02; C08G 2261/95; H01L 51/0036; H01L 51/0043; H01L 51/5076; H01L 51/5056; H01L 51/5092; C08G 2261/148; C08G 2261/411; C08G 2261/1422; C08G 2261/1426; C08G 2261/143; C08G 2261/3142; C08G 2261/3246; C08G 2261/792; H01L 51/0039

(57) ABSTRACT

A method of forming a polymer comprising repeat units of formula (II) or a salt thereof by forming a precursor polymer of formula (I) and converting the precursor polymer to the polymer comprising repeat units of formula (II): (Formulae (II), (III)) wherein BG is a backbone group; Sp¹ and Sp² are each a spacer group; x is 0 or 1; y is at least 1; X is O or NR² wherein R² is H or a substituent; P is selected from the group consisting of unsubstituted or substituted benzyl, CR¹₃, COR¹, COOR¹ or, if X═O, SiR¹₃; wherein R¹ in each occurrence is a C₁₋₂₀ hydrocarbyl group; R³ in each occurrence is a substituent; and z is 0 or a positive integer. The polymer of formula (II) may form a layer of an organic electronic device and the layer may be formed by deposition of the polymer dissolved in a polar solvent.

### FIELD OF THE INVENTION

The invention relates to methods of forming organic electronic devices, in particular organic light-emitting devices, using solution deposition methods.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating. However, if adjacent layers are formed by solution processing methods then the first layer to be deposited may partially or completely dissolve in the solvent used to deposit an adjacent layer.

An organic light-emitting device has a substrate carrying an anode, a cathode and an organic light-emitting layer containing a light-emitting material between the anode and cathode.

In operation, holes are injected into the device through the anode and electrons are injected through the cathode. Holes in the highest occupied molecular orbital (HOMO) and electrons in the lowest unoccupied molecular orbital (LUMO) of the light-emitting material combine to form an exciton that releases its energy as light.

Cathodes include a single layer of metal such as aluminium, a bilayer of calcium and aluminium as disclosed in WO 98/10621; and a bilayer of a layer of an alkali or alkali earth compound and a layer of aluminium as disclosed in L. S. Hung, C. W. Tang, and M. G. Mason, Appl. Phys. Lett. 70, 152 (1997).

An electron-transporting or electron-injecting layer may be provided between the cathode and the light-emitting layer.

Bao et al, “Use of a 1H-Benzoimidazole Derivative as an n-Type Dopant and To Enable Air-Stable Solution-Processed n-Channel Organic Thin-Film Transistors” J. Am. Chem. Soc. 2010, 132, 8852-8853 discloses doping of [6,6]-phenyl C₆₁ butyric acid methyl ester (PCBM) by mixing (4-(1,3-dimethyl-2,3-dihydro-1H-benzoimidazol-2-yl)phenyl)dimethylamine (N-DMBI) with PCBM and activating the N-DMBI by heating.

U.S. Pat. No. 8,920,944 discloses n-dopant precursors for doping organic semiconductive materials.

Naab et al, “Mechanistic Study on the Solution-Phase n-Doping of 1,3-Dimethyl-2-aryl-2,3-dihydro-1H-benzoimidazole Derivatives”, J. Am. Chem. Soc. 2013, 135, 15018-15025 discloses that n-doping may occur by a hydride transfer pathway or an electron transfer pathway.

WO 2012/133229 discloses an OLED comprising a charge injection or charge transport layer containing a polymer having a structural unit containing a carboxylate salt substituent.

Lee et al, Adv. Funct. Mater. 2009, 19, 3317-3325 discloses a conjugated polymer and molecular beacon-based solid-state DNA sensing system for label-free detection.

Synthesis of oligonucleotides substituted with trityl groups is disclosed in WO 2008/143929.

It is an object of the invention to provide organic electronic devices comprising adjacent layers formed by solution processing.

### SUMMARY OF THE INVENTION

In a first aspect the invention provides a method of forming a polymer comprising repeat units of formula (II) or a salt thereof:

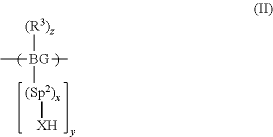

the method comprising the steps of forming a precursor polymer comprising repeat units of formula (I) by polymerising a monomer of formula (Im) and converting the precursor polymer comprising repeat units of formula (I) to a polymer comprising repeat units of formula (II) or a salt thereof:

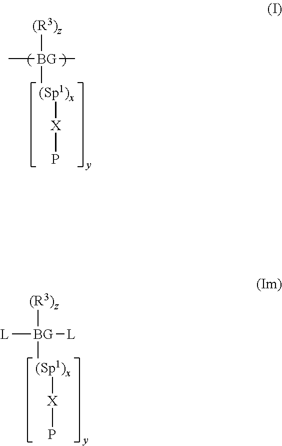

wherein BG is a backbone group; Sp¹ and Sp² are each a spacer group; x is 0 or 1; y is at least 1; X is O or NR² wherein R² is H or a substituent; P is selected from the group consisting of unsubstituted or substituted benzyl, CR¹₃, COR¹, COOR¹ or, if X═O, SiR¹₃; wherein R¹ in each occurrence is a C₁₋₂₀ hydrocarbyl group; R³ in each occurrence is a substituent; z is 0 or a positive integer; and each L is independently a leaving group.

In a second aspect the invention provides a method of forming an organic electronic device comprising adjacent first and second organic layers, the method comprising the steps of:

converting a precursor polymer comprising repeat units of formula (I) to a polymer comprising repeat units of formula (II) or a salt thereof:

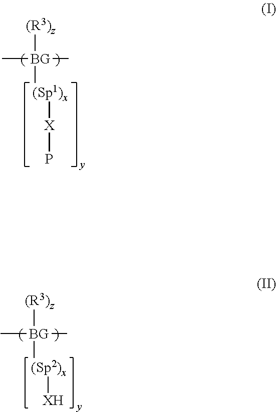

wherein BG is a backbone group; Sp¹ and Sp² are each a spacer group; x is 0 or 1; y is at least 1; X is O or NR² wherein R² is H or a substituent; P is selected from the group consisting of unsubstituted or substituted benzyl, CR¹₃, COR¹, COOR¹ or, if X═O, SiR¹₃; wherein R¹ in each occurrence is a C₁₋₂₀ hydrocarbyl group; R³ in each occurrence is a substituent; and z is 0 or a positive integer;

forming the first organic layer by depositing a first solution comprising one or more materials dissolved in a non-polar solvent; and

forming the second organic layer by depositing a second solution comprising the polymer comprising repeat units of formula (II) dissolved in a polar solvent.

### DESCRIPTION OF THE DRAWINGS

The invention will now be described in more detail with reference to the drawings in which:

FIG. 1 illustrates schematically an OLED according to an embodiment of the invention.

### DETAILED DESCRIPTION OF THE INVENTION

The formation of organic electronic devices as described herein includes the steps of forming a first organic layer by depositing a first formulation comprising one or more materials dissolved in a non-polar solvent; and forming a second organic layer by depositing a second formulation comprising one or more materials including the polymer comprising repeat units of formula (II) dissolved in a polar solvent.

“Solvent” as used herein includes a single solvent or a mixture of two or more solvents. A non-polar solvent may consist of a single non-polar solvent or a plurality of non-polar solvents. A polar solvent may consist of a single polar solvent or a plurality of polar solvents.

The first and second layers are adjacent. The first layer may be formed followed by formation of the second layer on the first layer, or the second layer may be formed followed by formation of the first layer.

If the first layer is formed first followed by deposition onto the first layer of the material or materials for formation of the second layer then the or each material of the first layer is preferably insoluble in the polar solvent used to deposit the material or materials for formation of the second organic layer.

If the second layer is deposited followed by deposition onto the second layer of the material or materials for formation of the first layer then the or each material of the second layer is preferably insoluble in the non-polar solvent used to deposit the material or materials for formation of first organic layer.

By “insoluble” as used herein is meant a solubility of less than 0.01 wt % in the solvent at 20° C.

Preferably, the or each material deposited to form the first layer has a solubility of at least 0.1 wt %, preferably at least 0.2 wt %, in the non-polar solvent at 20° C.

Preferably, the or each material deposited to form the second layer has a solubility of at least 0.1 wt %, preferably at least 0.2 wt %, in the polar solvent at 20° C.

Non polar solvents are preferably aprotic. Exemplary non-polar solvents are chloroform, benzenes substituted with one or more substituents selected from C₁₋₁₀ alkyl and C₁₋₁₀ alkoxy groups, for example toluene, xylenes and methylanisoles, and mixtures thereof. Non polar aprotic solvents are preferably aprotic solvents having a dielectric constant at 20° C. of less than 8.

Polar solvents may be protic or aprotic. Exemplary protic solvents are water and alcohols, for example methanol ethanol, propanol, butoxyethanol, ethylene glycol, 1-methoxy-2-propanol and monofluoro-, polyfluoro- or perfluoro-alcohols, optionally 2,2,3,3,4,4,5,5-octafluoro-1-pentanol. Exemplary aprotic polar solvents are dimethylsulfoxide; propylene carbonate; and 2-butanone. Aprotic polar solvents preferably have a dielectric constant at 20° C. of at least 15 or at least 20.

Exemplary solution deposition techniques include printing and coating techniques such spin-coating, inkjet printing and lithographic printing, dip-coating, slot die coating, roll printing and screen printing.

Preferably, the organic electronic device comprising the adjacent first and second layers is an OLED wherein the first layer is a light-emitting layer of the OLED and the second layer is an electron injection layer of the OLED.

Formation of an organic electronic device is described hereinafter with reference to formation of the light-emitting layer and electron-transporting or electron-injection layer of an OLED, however it will be appreciated that adjacent layers of other organic electronic devices or other adjacent functional organic layers of an OLED may be formed by the methods described herein.

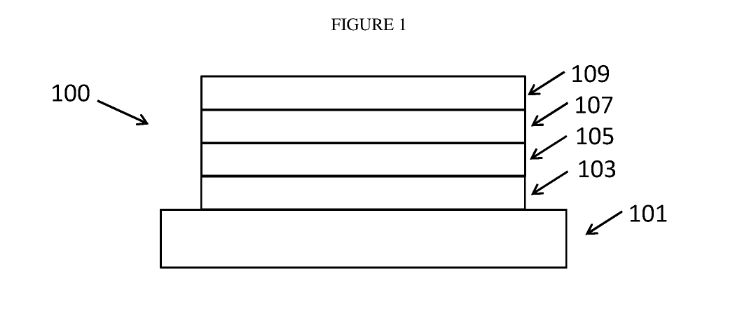

FIG. 1, which is not drawn to any scale, illustrates an OLED 100 according to an embodiment of the invention supported on a substrate 101, for example a glass or plastic substrate. The OLED 100 comprises an anode 103, a light-emitting layer 105, an electron-transporting layer 107 and a cathode 109.

The OLED 100 may be a display, optionally a full-colour display wherein the light-emitting layer 105 comprises pixels comprising red, green and blue subpixels.

The OLED 100 may be a white-emitting OLED. White-emitting OLEDs as described herein may have a CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-6000K. A white-emitting OLED may contain a plurality of light-emitting materials, preferably red, green and blue light-emitting materials, more preferably red, green and blue phosphorescent light-emitting materials, that combine to produce white light. The light-emitting materials may all be provided in light-emitting layer 105, or one or more additional light-emitting layers may be provided.

A red light-emitting material may have a photoluminescence spectrum with a peak in the range of about more than 550 up to about 700 nm, optionally in the range of about more than 560 nm or more than 580 nm up to about 630 nm or 650 nm.

A green light-emitting material may have a photoluminescence spectrum with a peak in the range of about more than 490 nm up to about 560 nm, optionally from about 500 nm, 510 nm or 520 nm up to about 560 nm.

A blue light-emitting material may have a photoluminescence spectrum with a peak in the range of up to about 490 nm, optionally about 450-490 nm.

The photoluminescence spectrum of a material may be measured by casting 5 wt % of the material in a PMMA film onto a quartz substrate and measuring in a nitrogen environment using apparatus C9920-02 supplied by Hamamatsu.

The anode 103 may be single layer of conductive material or may be formed from two or more conductive layers. Anode 103 may be a transparent anode, for example a layer of indium-tin oxide. A transparent anode 103 and a transparent substrate 101 may be used such that light is emitted through the substrate. The anode may be opaque, in which case the substrate 101 may be opaque or transparent, and light may be emitted through a transparent cathode 109.

Cathode 109 is formed of at least one layer, optionally two or more layers, for injection of electrons into the device. Preferably, the cathode is adjacent to electron-transporting layer 107.

Light-emitting layer 105 contains at least one light-emitting material. Light-emitting material 105 may consist of a single light-emitting compound or may be a mixture of more than one compound, optionally a host doped with one or more light-emitting dopants. Light-emitting layer 105 may contain at least one light-emitting material that emits phosphorescent light when the device is in operation, or at least one light-emitting material that emits fluorescent light when the device is in operation. Light-emitting layer 105 may contain at least one phosphorescent light-emitting material and at least one fluorescent light-emitting material.

Electron-transporting layer 107 is adjacent to light-emitting layer 105 and comprises or consists of an undoped electron-transporting material. Electron-transporting layer 107 comprises a polymer comprising a repeat unit of formula (II).

Preferably, the electron-transporting material has a LUMO that is no more than about 1 eV, optionally less than 0.5 eV or 0.2 eV, deeper (further from vacuum) than a LUMO of a material of the light-emitting layer, which may be a LUMO of a light-emitting material or a LUMO of a host material if the light-emitting layer comprises a mixture of a host material and a light-emitting material. Optionally, the electron-transporting material has a LUMO of less than 3.2 or 3.0 eV from vacuum level, optionally around 2.1-2.8 eV.

HOMO and LUMO levels as described anywhere herein are as measured by square wave voltammetry.

In another embodiment, the OLED is as described above except that the layer 107 is an electron injection layer comprising or consisting of an electron-transporting material that is doped by an n-dopant.

In the case where layer 107 is an electron-transporting layer, the polymer comprising repeat units of formula (II) is preferably the electron-transporting material.

In the case where layer 107 is an electron-injection layer, the polymer comprising repeat units of formula (II) may be an electron-accepting material and the n-dopant may be mixed with the polymer or covalently bound thereto. The polymer comprising repeat units of formula (II) may be substituted with the n-dopant that is mixed in the electron-injection layer with a separate electron-accepting material.

The OLED 100 may contain one or more further layers between the anode 103 and the cathode 109, for example one or more charge-transporting, charge-blocking or charge-injecting layers. Preferably, the device comprises a hole-injection layer comprising a conducting material between the anode and the light emitting layer 105. Preferably, the device comprises a hole-transporting layer comprising a semiconducting hole-transporting material between the anode 103 and the light emitting layer 105.

Light-emitting layer 105 is formed by depositing the or each material of the light-emitting layer from a solution in a non-polar solvent followed by evaporation of the solvent. The light-emitting layer may consist of one or more light-emitting materials or may comprise one or more further materials as described herein.

Electron-transporting or injecting layer 107 is formed by depositing the polymer comprising a repeat unit of formula (II) from a solution in a polar solvent followed by evaporation of the solvent. The polymer comprising a repeat unit of formula (II) may be the only solute of the solution or the solution may comprise one or more further dissolved materials.

The non-polar and polar solvents may each independently be evaporated at room temperature or at an elevated temperature, optionally in the range of about 50-180° C.

Each of the light-emitting layer 105 and the electron-transporting or injecting layer 107 are preferably formed in air.

In the repeat unit of formula (II), BG is preferably an at least partially conjugated group that is directly conjugated to adjacent repeat units in the polymer backbone.

Preferably, BG is a C₆₋₂₀ arylene group, more preferably fluorene.

y is at least 1, optionally 1, 2, 3 or 4.

Substituents R³, if present, may be selected from linear, branched or cyclic C₁₋₂₀ alkyl groups wherein one or more non-adjacent, non-terminal C atoms of the alkyl group may be replaced with O, S, COO or CO and unsubstituted or substituted C₆₋₂₀ aryl, preferably phenyl, that may be unsubstituted or substituted with one or more substituents, optionally one or more substituents selected from linear, branched or cyclic C₁₋₂₀ alkyl groups wherein one or more non-adjacent, non-terminal C atoms of the alkyl group may be replaced with O, S, COO or CO; COOR⁴ wherein R⁴ is a C₁₋₁₀ hydrocarbyl group or COO-M+ wherein M+ is a metal or organic cation, preferably an alkali metal cation. The or each substituent R³, if present, may be selected according to the required solubility of the polymer in a polar solvent.

By “non-terminal C atom of an alkyl group” as used herein means a C atom other than the methyl group of a n-alkyl chain or the methyl groups of a branched alkyl chain.

The spacer group Sp¹ is preferably a C₁₋₁₂ n-alkylene group wherein one or more non-adjacent C atoms of the alkylene group may be replaced with O, S, CO, COO, N—P or an arylene or heteroarylene group, preferably phenyl, that may be unsubstituted or substituted with one or more substituents, and one or more H atoms may be replaced with F or C₁₋₄ alkyl. The or each substituent of an arylene or heteroarylene group, if present, may independently be selected from C₁₋₁₂ alkyl or C₁₋₁₂ alkoxy.

The spacer group Sp¹ is preferably a C₁₋₁₂ n-alkylene group; a phenylene-C₁₋₁₂ alkylene group; or a spacer group comprising N—P, optionally a C₃₋₁₂ alkylene chain wherein a non-terminal C atom of the alkylene chain is replaced with N—P. If the spacer group Sp¹ comprises a group N—P then corresponding spacer group Sp² comprises a group N—H.

If the spacer group Sp¹ does not comprise a group N—P then Sp¹ and Sp² are preferably the same.

X is preferably NR² wherein R² is H or a substituent. Exemplary substituents R² are C₁₋₁₂ hydrocarbyl, preferably C₁₋₁₂ alkyl.

The repeat unit of formula (II) is optionally selected from phenylene repeat units, optionally a 1,4-phenylene repeat unit, a phenanthrene repeat unit, and a fluorene repeat unit substituted with at least one group of formula -(Sp²)x-XH and optionally substituted with one or more substituents R³.

The repeat unit of formula (II) may have formula (IIa) or (IIb):

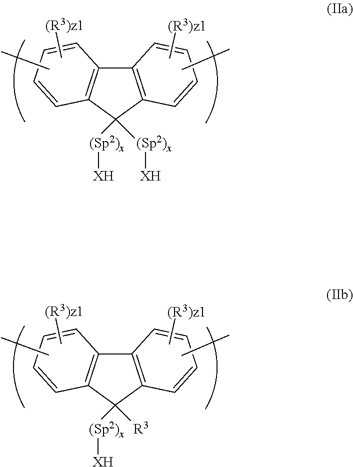

wherein Sp², x, X and R³ are as described above and z1 is 0 or 1, preferably 0.

Preferably, the fluorene unit of formula (IIa) or (IIb) is a 2,7-linked fluorene unit.

Repeat units of formula (II) optionally make up 5-80 mol % of the repeat units of the polymer, the remaining repeat units being co-repeat units of the polymer.

Co-repeat units may be arylene repeat units, optionally C₆₋₂₀ arylene repeat units, and 5-20 membered heteroaromatic repeat units, optionally 5-20 membered heteroaromatic repeat units of C, N, S and O atoms.

Arylene and heteroarylene repeat units may be unsubstituted or substituted with one or more substituents, optionally one or more substituents R³.

Arylene co-repeat units include, without limitation, fluorene, phenylene, naphthalene, anthracene, indenofluorene, phenanthrene and dihydrophenanthrene repeat units, optionally repeat units of formulae (III)-(VI), each of which may be unsubstituted or substituted with one or more substituents:

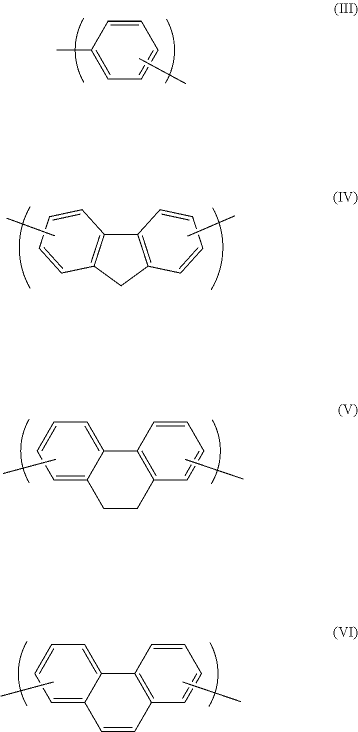

Co-repeat units of formulae (III)-(VI) may have formulae (IIIa)-(VIa) respectively:

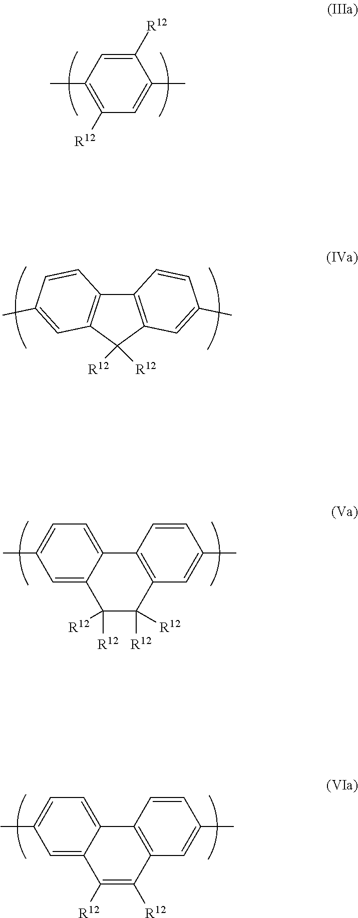

wherein each R¹² is independently a substituent.

The substituent or substituents R¹² may be selected according to the required solubility of the polymer in a polar solvent, and one or more, optionally all, substituents R¹² may be selected from substituents R³ described with reference to Formula (II).

The polymer comprising repeat units of formula (II) may be an electron-transporting polymer and the repeat units of the polymer and the substituents thereof may be selected accordingly. The electron-transporting polymer may comprise repeat units comprising a polar double or triple bond, optionally a bond selected from a C═N (imino) group, a nitrile group, a C═S group, an oxime group or a C═O group, optionally a keto, ester or carbonate group. Preferably, these polar double- or triple-bond groups are conjugated to a conjugated polymer backbone. These polar double- or triple-bond groups may be provided as substituents of a conjugated co-repeat unit, optionally substituents R¹², or may be part of a conjugated co-repeat unit, for example fluorenone, or benzothiodiazole

In the case where the polymer comprising repeat units of formula (II) is in an electron-injection layer, one or more substituents of a co-repeat unit, optionally a substituent R¹² may comprise an n-dopant.

Polymers as described anywhere herein suitably have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of polymers described anywhere herein may be 1×10³ to 1×10⁸, and preferably 1×10⁴ to 1×10⁷.

Polymers as described anywhere herein are suitably amorphous polymers.

n-Dopant

In the case where the second organic layer is an electron injection layer, the layer comprises an electron-transporting material and an n-dopant. One or both of the electron-transporting material and the n-dopant may be a polymer comprising a repeat unit of formula (II).

The n-dopant may be provided as a substituent of a repeat unit of a polymer, optionally a polymer comprising a repeat unit of formula (II).

The n-dopant may be bound directly to the polymer backbone or may be spaced apart from the polymer backbone by a spacer group. A spacer group may be a C₁₋₂₀ alkylene chain wherein one or more C atoms spacing the n-dopant from the polymer backbone may be replaced by O, S, CO or COO or unsubstituted or substituted arylene or heteroarylene, optionally phenyl that may be unsubstituted or substituted with one or more C₁₋₁₂ alkyl or alkoxy groups.

The n-dopant may spontaneously dope the electron-transporting (acceptor) material to form a charge-transfer salt, or n-doping may occur upon activation, for example heat or irradiation of the n-dopant and acceptor. The electron-injecting layer may comprise or consist of the charge-transfer salt. Optionally, the n-dopant has a HOMO level that is the same as or, preferably, deeper (further from vacuum) than the LUMO level of the electron-transporting material, optionally at least 1 eV or 1.5 eV deeper than the LUMO level of the electron-transporting material. Accordingly, little or no spontaneous doping occurs upon mixing of the electron-transporting material and such an n-dopant at room temperature

Preferably, n-doping is effected after formation of a device comprising the second organic layer containing the electron-transporting material and n-dopant, and optionally after encapsulation. Activation may be by excitation of the n-dopant and/or the electron-transporting material.

Exemplary activation methods are thermal treatment and irradiation.

Optionally, thermal treatment is at a temperature in the range 80° C. to 170° C., preferably 120° C. to 170° C. or 140° C. to 170° C.

Thermal treatment and irradiation as described herein may be used together.

For irradiation, any wavelength of light may be used, for example a wavelength having a peak in the range of about 200-700 nm.

Optionally, the peak showing strongest absorption in the absorption spectrum of the electron-transporting material is in the range of 400-700 nm. Preferably, the strongest absorption of the n-dopant is at a wavelength below 400 nm.

The light emitted from the light source suitably overlaps with an absorption feature, for example an absorption peak or shoulder, of the electron-transporting material's absorption spectrum. Optionally, the light emitted from the light source has a peak wavelength within 25 nm, 10 nm or 5 nm of an absorption maximum wavelength of the electron-transporting material, however it will be appreciated that a peak wavelength of the light need not coincide with an absorption maximum wavelength of the electron-transporting material.

The extent of doping may be controlled by one or more of: the electron-transporting material/n-dopant ratio; the peak wavelength of the light; the duration of irradiation of the film; the temperature; and the intensity of the light. It will be appreciated that excitation will be most efficient when a peak wavelength of the light coincides with an absorption maximum of the electron-transporting material.

The device may be manufactured in an environment in which little or no spontaneous doping occurs, for example a room temperature environment wherein the n-dopant and electron-transporting material are exposed to little or no wavelengths of light that induce n-doping until after encapsulation of the device, for example an environment illuminated by light having a longer wavelength than that of the electromagnetic radiation source such as a clean room illuminated with yellow light.

Exemplary n-dopants comprise a 2,3-dihydro-benzoimidazole group, optionally a 2,3-dihydro-1H-benzoimidazole group.

The n-dopant is preferably a group of formula (III):

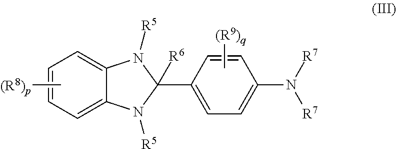

wherein:

each R⁵ is independently a C₁₋₂₀ hydrocarbyl group, optionally a C₁₋₁₀ alkyl group;

R⁶ is H or a C₁₋₂₀ hydrocarbyl group, optionally H, C₁₋₁₀ alkyl or C₁₋₁₀ alkylphenyl; and

each R⁷ is independently a C₁₋₂₀ hydrocarbyl group, optionally C₁₋₁₀ alkyl, phenyl or phenyl substituted with one or more C₁₋₁₀ alkyl groups;

each R⁸ or R⁹ is a C₁₋₁₂ hydrocarbyl group; and

p and q are each 0 or a positive integer, with the proviso that one of R⁵-R⁹ is a direct bond to a spacer group or to a polymer backbone in the case where the group of formula (III) is provided as the substituent of a polymeric repeating unit.

Exemplary n-dopants include the following, each of which may be provided as a separate molecule in the electron injection layer or as a substituent of a polymer, optionally a polymer comprising repeat units of formula (II):

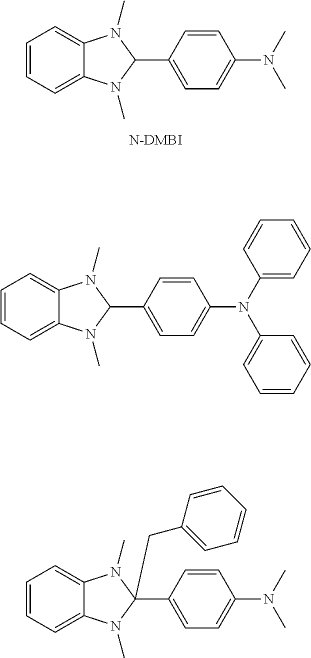

N-DMBI is disclosed in Adv. Mater 2014, 26, 4268-4272, the contents of which are incorporated herein by reference.

Exemplary n-dopant groups bound to a polymer backbone include the following:

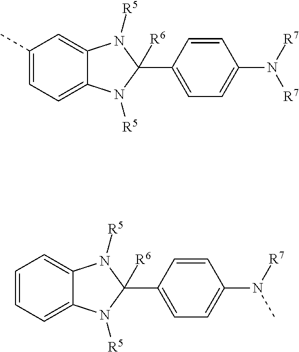

wherein --- is a bond to a backbone group of a polymeric repeating unit or to a spacer group of the polymeric repeating unit.

Other exemplary n-dopants are leuco crystal violet disclosed in J. Phys. Chem. B, 2004, 108 (44), pp 17076-17082, the contents of which are incorporated herein by reference, and NADH.

Polymer Formation

If the precursor polymer comprising repeat units of formula (I) is a conjugated polymer then it may be formed by polymerising monomers comprising leaving groups that leave upon polymerisation of the monomers in the presence of a metal catalyst, preferably a nickel or palladium catalyst, to form conjugated repeat units.

Exemplary polymerization methods include, without limitation, Yamamoto polymerization as described in, for example, T. Yamamoto, “Electrically Conducting And Thermally Stable pi-Conjugated Poly(arylene)s Prepared by Organometallic Processes”, Progress in Polymer Science 1993, 17, 1153-1205, the contents of which are incorporated herein by reference and Suzuki polymerization as described in, for example, WO 00/53656, the contents of which are incorporated herein by reference.

Preferably, the precursor polymer is formed by polymerising monomers comprising boronic acid or boronic ester group leaving groups bound to aromatic carbon atoms of the monomer with monomers comprising leaving groups selected from halogen, sulfonic acid or sulfonic ester, preferably bromine or iodine, bound to aromatic carbon atoms of the monomer.

The polymerisation is preferably carried out in the presence of a palladium (0) or palladium (II) catalyst, a phosphine and a base.

The base may be an organic or inorganic base. Exemplary organic bases include tetra-alkylammonium hydroxides, carbonates and bicarbonates. Exemplary inorganic bases include metal (for example alkali or alkali earth) hydroxides, carbonates and bicarbonates.

The phosphine may be provided, either as a ligand of the palladium compound catalyst or as a separate compound added to the polymerisation mixture. Exemplary phosphines include triarylphosphines, for example triphenylphosphines wherein each phenyl may independently be unsubstituted or substituted with one or more substituents, for example one or more Cᵢₛ alkyl or Cᵢₛ alkoxy groups. Exemplary phosphines are as disclosed in J. Am. Chem. Soc. 2005, 127, 4685-4696, WO 2003/035796, WO 00/53656 and U.S. Pat. No. 5,777,070, the contents of which are incorporated herein by reference, for example triphenylphospine, tris(ortho-methoxytriphenyl) phosphine and 2-dicyclohexylphosphino-2′,6′-dimethoxybiphenyl (Sphos).

Preferably, the polymer comprising repeat units of formula (I) is formed by polymerizing monomers of formula (Im):

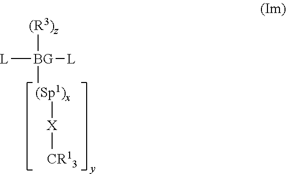

wherein L is a leaving group, preferably a leaving group as described above, preferably a boronic acid or ester or a halogen, sulfonic acid or sulfonic ester, preferably bromine or iodine.

Exemplary boronic esters have formula (XII):

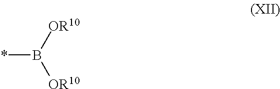

wherein R¹⁰ in each occurrence is independently a C₁₋₂₀ alkyl group, * represents the point of attachment of the boronic ester to an aromatic ring of the monomer, and the two groups R¹⁰ may be linked to form a unsubstituted ring or a ring substituted with one or more C₁₋₄ alkyl groups.

Metal-catalysed polymerisation methods as described above for forming such polymers may be carried out in a two-phase system in which the monomer of formula (Im) is dissolved in a non-polar solvent of the two phase system.

The monomer of formula (Im) is substituted with at least one substituent of formula —P that may enhance solubility of the monomer, and resulting polymer, in the non-polar solvent used for polymerisation. P is selected from unsubstituted or substituted benzyl, CR¹₃, a carbonyl group COR¹ or COOR¹ or, if X═O, SiR¹₃; wherein the substituent R¹ is independently in each occurrence a C₁₋₂₀ hydrocarbyl group, optionally a C₁₋₂₀ alkyl group, an unsubstituted phenyl group or a phenyl group substituted with one or more C₁₋₁₂ alkyl groups.

Preferably, in the case where P is CR¹₃, each R¹ is unsubstituted phenyl or branched alkyl, optionally isopropyl or tert-butyl.

Substituents of a benzyl group P, if present, are optionally selected from C₁₋₁₂ alkyl or C₁₋₁₂ alkoxy.

After formation of the polymer comprising repeat units of formula (I), the groups of formula P present in the polymer are removed to form a polymer comprising repeat units of formula (II) to enhance solubility of the polymer comprising repeat units of formula (II), or salts thereof, in polar solvents as compared to polar solvent solubility of the precursor polymer comprising repeat units of formula (I).

Removal may be by acid treatment, optionally treatment with a fluorinated acid such as trifluoroacetic acid.

In the case where X—P of formula (I) is —NR²P, or Sp¹ of formula (I) comprises a group N—P, then removal of the group P may result in formation of a group NR²H or N—H respectively, or an ammonium salt thereof.

Anions of the ammonium salt may be selected from, without limitation, halide, acetate, and trifluoroacetate. It will be understood that the anion may be selected according to the acid used for removal of group P.

Light-Emitting Layers

The OLED 100 may contain one or more light-emitting layers.

Light-emitting materials of the OLED 100 may be fluorescent materials, phosphorescent materials or a mixture of fluorescent and phosphorescent materials. Light-emitting materials may be selected from polymeric and non-polymeric light-emitting materials.

Exemplary light-emitting polymers are conjugated polymers, for example polyphenylenes and polyfluorenes examples of which are described in Bernius, M. T., Inbasekaran, M., O'Brien, J. and Wu, W., Progress with Light-Emitting Polymers. Adv. Mater., 12 1737-1750, 2000, the contents of which are incorporated herein by reference. Light-emitting layer 107 may comprise a host material and a fluorescent or phosphorescent light-emitting dopant. Exemplary phosphorescent dopants are row 2 or row 3 transition metal complexes, for example complexes of ruthenium, rhodium, palladium, rhenium, osmium, iridium, platinum or gold.

A light-emitting layer of an OLED may be unpatterned, or may be patterned to form discrete pixels. Each pixel may be further divided into subpixels. The light-emitting layer may contain a single light-emitting material, for example for a monochrome display or other monochrome device, or may contain materials emitting different colours, in particular red, green and blue light-emitting materials for a full-colour display.

A light-emitting layer may contain a mixture of more than one light-emitting material, for example a mixture of light-emitting materials that together provide white light emission. A plurality of light-emitting layers may together produce white light.

A fluorescent light-emitting layer may consist of a light-emitting material alone or may further comprise one or more further materials mixed with the light-emitting material. Exemplary further materials may be selected from hole-transporting materials; electron-transporting materials and triplet-accepting materials, for example a triplet-accepting polymer as described in WO 2013/114118, the contents of which are incorporated herein by reference.

In the case where the first organic layer is a light-emitting layer, it is preferably formed by deposition from a solution of a non-polar solvent and the one or more materials dissolved in the non-polar solvent consist of one or more light-emitting materials or comprise one or more light-emitting materials and one or more further materials mixed with the light-emitting material, optionally one or more further materials as described above.

Cathode

The cathode may comprise one or more layers. Preferably, the cathode comprises or consists of a layer in contact with the electron injecting layer that comprises or consists of one or more conductive materials. Exemplary conductive materials are metals, preferably metals having a work function of at least 4 eV, optionally aluminium, copper, silver or gold or iron. Exemplary non-metallic conductive materials include conductive metal oxides, for example indium tin oxide and indium zinc oxide, graphite and graphene. Work functions of metals are as given in the CRC Handbook of Chemistry and Physics, 12-114, 87^{th} Edition, published by CRC Press, edited by David R. Lide. If more than one value is given for a metal then the first listed value applies.

The cathode may be opaque or transparent. Transparent cathodes are particularly advantageous for active matrix devices because emission through a transparent anode in such devices is at least partially blocked by drive circuitry located underneath the emissive pixels.

It will be appreciated that a transparent cathode device need not have a transparent anode (unless a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

Hole-Transporting Layer

A hole transporting layer may be provided between the anode 103 and the light-emitting layer 105.

The hole-transporting layer may be cross-linked, particularly if an overlying layer, preferably a light-emitting layer, is deposited from a solution. The crosslinkable group used for this crosslinking may be a crosslinkable group comprising a reactive double bond such and a vinyl or acrylate group, or a benzocyclobutane group. Crosslinking may be performed by thermal treatment, preferably at a temperature of less than about 250° C., optionally in the range of about 100-250° C.

Optionally, the hole-transporting layer is formed by depositing a non-polar solution comprising a hole-transporting material and crosslinking the hole-transporting material followed by formation of the first organic layer, preferably a light-emitting layer, on the hole-transporting layer and the second organic layer, preferably an electron-transporting or electron injection layer, on the light-emitting layer.

A hole transporting layer may comprise or may consist of a hole-transporting polymer, which may be a homopolymer or copolymer comprising two or more different repeat units. The hole-transporting polymer may be conjugated or non-conjugated. Exemplary conjugated hole-transporting polymers are polymers comprising arylamine repeat units, for example as described in WO 99/54385 or WO 2005/049546 the contents of which are incorporated herein by reference. Conjugated hole-transporting copolymers comprising arylamine repeat units may have one or more co-repeat units selected from arylene repeat units, for example one or more repeat units selected from fluorene, phenylene, phenanthrene naphthalene and anthracene repeat units, each of which may independently be unsubstituted or substituted with one or more substituents, optionally one or more C₁₋₄₀ hydrocarbyl substituents.

If present, a hole transporting layer located between the anode and the light-emitting layer 105 preferably has a HOMO level of less than or equal to 5.5 eV, more preferably around 4.8-5.5 eV or 5.1-5.3 eV as measured by cyclic voltammetry. The HOMO level of the hole transport layer may be selected so as to be within 0.2 eV, optionally within 0.1 eV, of an adjacent layer in order to provide a small barrier to hole transport between these layers.

A hole-transporting layer may consist essentially of a hole-transporting material or may comprise one or more further materials. A light-emitting material, optionally a phosphorescent material, may be provided in the hole-transporting layer.

A phosphorescent material may be covalently bound to a hole-transporting polymer as a repeat unit in the polymer backbone, as an end-group of the polymer, or as a side-chain of the polymer. If the phosphorescent material is provided in a side-chain then it may be directly bound to a repeat unit in the backbone of the polymer or it may be spaced apart from the polymer backbone by a spacer group. Exemplary spacer groups include C₁₋₂₀ alkyl and aryl-C₁₋₂₀ alkyl, for example phenyl-C₁₋₂₀ alkyl. One or more carbon atoms of an alkyl group of a spacer group may be replaced with O, S, C═O or COO.

Emission from a light-emitting hole-transporting layer and emission from an adjacent light-emitting layer 105 may combine to produce white light.

Hole Injection Layers

A conductive hole injection layer, which may be formed from a conductive organic or inorganic material, may be provided between the anode 103 and the light-emitting layer 105 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

Encapsulation

In the case where an electron-injection layer comprises an n-dopant that does not spontaneously dope the electron-transporting material, the n-dopant is preferably activated to cause n-doping as described herein after encapsulation of the device to prevent ingress of moisture and oxygen.

Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

The substrate on which the device is formed preferably has good barrier properties such that the substrate together with the encapsulant forms a barrier against ingress of moisture or oxygen. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

Applications

The first and second organic layers have been described with reference to a light-emitting layer and an electron-transporting layer or electron-injection layer of an organic light-emitting device, however it will be appreciated that the layers formed as described herein may be used in other organic electronic devices, for example in an organic photovoltaic device or organic photodetector; organic thin film transistor or a thermoelectric generator.

Measurements

HOMO and LUMO levels as described anywhere herein are as measured by square wave voltammetry.

Equipment:

CHI660D Electrochemical workstation with software (IJ Cambria Scientific Ltd))

CHI 104 3 mm Glassy Carbon Disk Working Electrode (IJ Cambria Scientific Ltd))

Platinum Wire Auxiliary Electrode

Reference Electrode (Ag/AgCl) (Havard Apparatus Ltd)

Chemicals

Acetonitrile (Hi-dry anhydrous grade-ROMIL) (Cell solution solvent)

Toluene (Hi-dry anhydrous grade) (Sample preparation solvent)

Ferrocene—FLUKA (Reference standard)

Tetrabutylammoniumhexafluorophosphate—FLUKA) (Cell solution salt)

Sample Preparation

The acceptor polymers were spun as thin films (˜20 nm) onto the working electrode; the dopant material was measured as a dilute solution (0.3 w %) in toluene.

Electrochemical Cell

The measurement cell contains the electrolyte, a glassy carbon working electrode onto which the sample is coated as a thin film, a platinum counter electrode, and a Ag/AgCl reference glass electrode. Ferrocene is added into the cell at the end of the experiment as reference material (LUMO (ferrocene)=−4.8 eV).

### EXAMPLES

### Monomer Example 1

Monomer Example 1 was prepared according to the following reaction scheme:

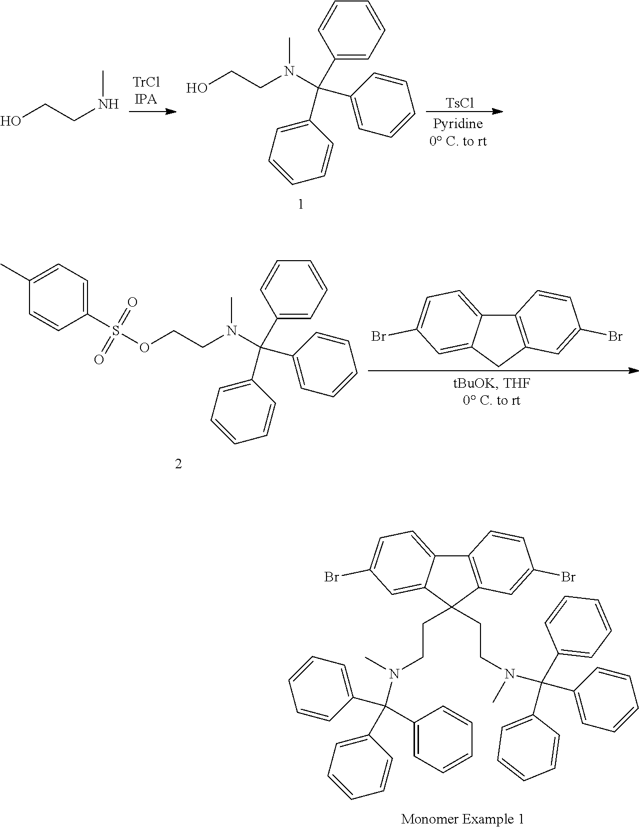

Intermediate 1:

Tritylchloride (64.95 g, 233.0 mmol) was added portion wise to a solution of 2-(methylamino)ethan-1-ol (70.0 g, 931.95 mmol) in 2-propanol (700 ml) at −10° C. Mixture was stirred at room temperature overnight. Reaction mixture was concentrated under reduced pressure. Residue was dissolved in toluene (500 ml), wash with water (150 ml×3), dried over magnesium sulphate and concentrated to dryness under vacuum to obtain Intermediate 1 as an oil, 72.0 g, 97% yield.

Intermediate 2:

Tosyl chloride (65.0 g, 340.2 mmol) was added portion wise at 0° C. to a solution of Intermediate 1 (72.0 g, 226.8 mmol) in pyridine (700 ml). Reaction was stirred at room temperature overnight. Pyridine was removed under reduced pressure and residue was dissolved in toluene (500 ml). Toluene solution was washed with water (150 ml×3), dried over magnesium sulphate, concentrated under reduced pressure and dried in vacuum oven at 50° C. for 70 hours. Product was dissolved in a mixture of dichloromethane:heptane (6:4), filtered through a basic alumina plug, using dichloromethane:heptane (6:4) as eluent. Fractions containing product were combined and concentrated to dryness under reduced pressure to obtain Intermediate 2 as a brown oil, 87 g, 81% yield.

### Monomer Example 1

Nitrogen was bubbled through a solution of 2,7-dibromfluorene (18.6 g, 57.3 mmol) in tetrahydrofuran (200 ml) for 1 hour. Potassium tert-butoxide (19.3 g, 171.8 mmol) was added portion wise to the solution at 15° C. and reaction was stirred for 1.5 hours at room temperature. Nitrogen was bubbled through a solution of Intermediate 2 (81 g, 171.8 mmol) in tetrahydrofuran (60 ml) for 30 minutes. It was added to the reaction mixture and stirred overnight at room temperature overnight. Reaction was filtered through a basic alumina plug, eluted with toluene. Filtrate was concentrated under reduced pressure. Residue was stirred with cold methanol and slurry was filtered. Solid was recrystallized from a mixture of toluene and methanol, filtered and dried in vacuum oven at 50° C. to yield Monomer Example 1 as a white solid, 35 g, 99.8% pure by HPLC, 65% yield.

¹H-NMR (600 MHz, MeOH-D₄): δ_{H} [ppm] 1.47 (m, 4H), 1.89 (s, 6H), 2.26 (m, 4H), 7.06 (m, 6H), 7.13 (m, 12H), 7.22 (d, J=7.7 Hz, 12H), 7.25 (2H), 7.28 (m, 4H).

### Monomer Example 2

Monomer Example 2 was prepared according to the following reaction scheme:

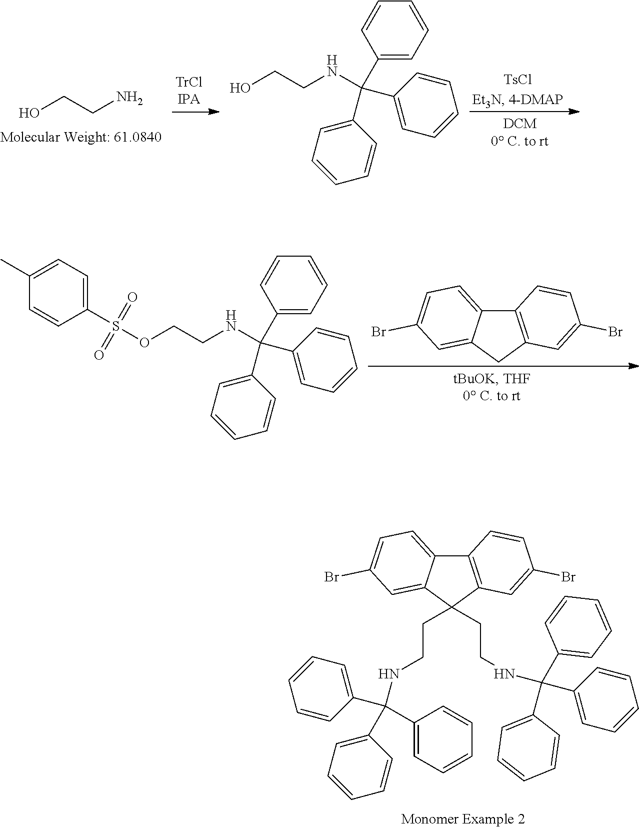

### 2-(tritylamino)ethan-1-ol

Tritylchloride (60.0 g, 215.2 mmol) was added portion wise to a solution of ethanolamine (52.0 ml, 860.9 mmol) in 2-propanol (215 ml) at 5° C. Mixture was stirred at room temperature for 1 hour. It was filtered and precipitated into cold water (400 ml). Solid was filtered, wash with water (×3) and dried in vacuum oven at 60° C. overnight to obtain 2-(tritylamino)ethan-1-ol as a white solid, 53.1 g, 81% yield.

### 2-(tritylamino)ethyl 4-methylbenzenesulfonate

Tosyl chloride (47.1 g, 247.2 mmol) was added in 5 portion to a solution of 2-(tritylamino)ethan-1-ol (50.0 g, 164.8 mmol), trimethylamine (34.5 ml, 247.2 mmol) and 4-(dimethylamino)pyridine (4.03 g, 33.0 mmol) in dichloromethane (300 ml) at 10° C. Mixture was stirred for 2.25 hours and filtered. Filtrate was washed with water (×3), ammonium hydroxide 3% aqueous (×2), water (×3), dried over magnesium sulphate and concentrated under vacuum to obtain 2-(tritylamino)ethyl 4-methylbenzenesulfonate as a white waxy solid, 75 g, 99% yield.

### Monomer Example 2

Nitrogen was bubbled through a solution of 2,7-dibromfluorene (17.7 g, 54.6 mmol) in tetrahydrofuran (300 ml) for 1 hour. Potassium tert-butoxide (18.4 g, 163.9 mmol) was added portion wise to the solution at 15° C. and reaction was stirred for 1.5 hours at room temperature. 2-(tritylamino)ethyl 4-methylbenzenesulfonate (75.0 g, 163.9 mmol) was added to the reaction mixture and stirred overnight at room temperature overnight. Reaction was filtered through a basic alumina plug, eluted with dichloromethane. Filtrate was concentrated under reduced pressure. Residue was stirred with acetonitrile and slurry was filtered. Solid was recrystallized twice from a mixture of toluene and acetonitrile, filtered and dried in vacuum oven at 50° C. Solid was dissolved in dichloromethane (500 ml), heptane (200 ml) was added to it and dichloromethane was removed under reduced pressure to give a slurry in heptane. It was filtered and dried. Solid was stirred for 2 hours in refluxing heptane (300 ml), cooled down to room temperature, filtered and dried in vacuum oven at 50° C. to yield Monomer Example 2 as a white solid, 20.9 g, 99.9% pure by HPLC, 43% yield.

¹H-NMR (600 MHz, MeOH-D₄): δ_{H} [ppm] 0.67 (s, 2H), 1.65 (m, 4H), 2.11 (t, J=6.2 Hz, 4H), 7.01 (m, 12H), 7.05-7.09 (m, 6H), 7.09-7.14 (m, 12H), 7.35 (d, J=1.0 Hz, 2H), 7.37 (d, J=8.0 Hz, 2H), 7.37 (dd, J=1.4 Hz, 8.1 Hz, 2H).

### Precursor Polymers 1-3

Precursor Polymers 1-3 were prepared by Suzuki polymerisation as described in WO 00/53656 of 50 mol % of a diester monomer and 50 mol % of a dibromide monomer as set out in Table 1, using a catalyst of either palladium acetate and tri(o-methylphenyl)phosphine (Precursor Polymers 1 and 3) or PdCl₂(SPhos)₂ (Precursor Polymer 2).

Polymer properties are provided in Table 2

TABLE 1

| Polymer | Diester monomer | Dibromide monomer |
|---|---|---|
| Precursor Polymer 1 | 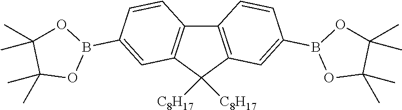 | Monomer Example 1 |
| Precursor Polymer 2 | 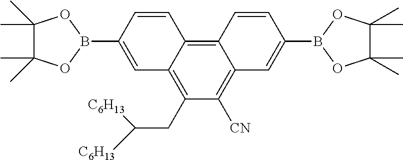 | Monomer Example 2 |
| Precursor Polymer 3 | 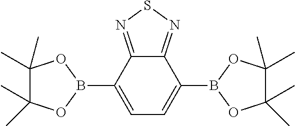 | Monomer Example 1 |

| Polymer | Mz | Mw | Mp | Mn | PD |
|---|---|---|---|---|---|
| Precursor | 152,000 | 82,000 | 77,000 | 29,000 | 2.78 |
| Polymer 1 | | | | | |
| Precursor | 141,000 | 72,000 | 108,000 | 18,000 | 4.01 |
| Polymer 2 | | | | | |
| Precursor | 47,000 | 25,000 | 23,000 | 11,000 | 2.29 |
| Polymer 3 | | | | | |

### Polymer Examples 1-3

Precursor polymers 1-3 were treated to form Polymer Examples 1-3 respectively.

Nitrogen was bubbled for 30 minutes into toluene (50 ml) and Trifluoroacetic acid (5 ml). Polymer Precursor 1 (1.0 g) was dissolved in toluene (50 ml). Trifluoroacetic acid (5 ml) was added to it and mixture was stirred for 3 hours at room temperature. Water (50 ml) was added at 0° C., mixture was stirred for 5 minutes and aqueous layer was removed. Ammonium hydroxide solution (3% aqueous, 50 ml) was added, mixture was stirred for 5 minutes and aqueous layer was removed. Water (50 ml) was added mixture was stirred for 5 minutes and precipitated into acetone. Slurry was filtered and solid was dried in vacuum oven at 50° C. to obtain Polymer Example 1, 0.51 g.

Polymer Precursor 2 was treated using the same procedure using Polymer Precursor 2 (2.1 g) toluene (105 ml), and trifluoroacetic acid (10.5 ml) in toluene solution (10.5 ml). 1.04 g of Polymer Example 2 was obtained.

Polymer Precursor 3 was treated using the same general procedure using Polymer Precursor 2 (1.0 g) chloroform (50 ml), and trifluoroacetic acid (5.0 ml). 0.52 g of Polymer Example 3 was obtained.

The change in solubility upon transformation of the precursor polymers 1-3 to respective polymer examples 1-3 is given in Table 2, in which OFP is 2,2,3,3,4,4,5,5-octafluoro-1-pentanol.

TABLE 2

| | Non polar solvent | Polar solvent |
|---|---|---|
| Polymer | solubility (wt %) | solubility (wt %) |
| Precursor Polymer 1 | >1 in toluene | None in methanol |
| Polymer Example 1 | None in toluene | 0.2 wt % in |
| | | methanol |
| Precursor Polymer 2 | >1 in toluene | None in methanol |
| Polymer Example 2 | None in toluene | >1 wt % in |
| | | methanol |
| Precursor Polymer 3 | >1 in chloroform | None in OFP |
| Polymer Example 3 | None in chloroform | 0.5 wt % OFP |

### Device Example 1

A blue OLED having the following structure was prepared:

Anode/LEL (65 nm)/EIL (20 nm)/Cathode (100 nm)

wherein Anode is a layer of ITO; LEL is a light-emitting layer; EIL is an electron injection layer; and Cathode is a layer of silver.

To form the device, Blue Polymer 1 was spin-coated onto ITO bottom contacts on glass, from a 1.3 w % solution in o-xylene in a glove box.

After drying at 150° C. for 15 min, a (20 nm) of Polymer Example 2 doped with 10 wt % Dopant 1 were spin-coated onto the light-emitting layer layer from a 0.4 w % solution in methanol, in a glove box.

After drying the resulting electron injection layer at 80° C. for 10 min, the device was then capped with a 100 nm thick thermally evaporated Ag top contact, and encapsulated with a glass can in a glove box.

Blue Polymer 1 is a blue fluorescent polymer comprising 2,7-linked fluorene repeat units and an amine repeat unit having the following structure formed by Suzuki polymerization as described in WO 00/53656:

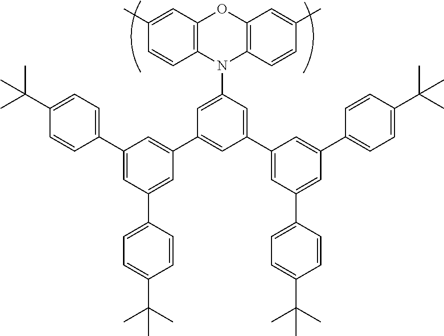

Dopant 1 has the following structure:

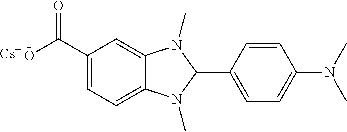

The device emitted blue light upon application of a bias.

Formation of a device having the structure of Device Example 1 in which the electron-injection layer is deposited from a non-polar solution was not possible due to dissolution of the underlying light-emitting layer.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A method of forming a polymer comprising repeat units of formula (II) or a salt thereof: 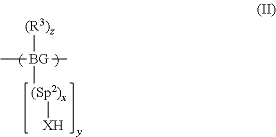
the method comprising the steps of forming a precursor polymer comprising repeat units of formula (I) by polymerising a monomer of formula (Im) and converting the precursor polymer comprising repeat units of formula (I) to a polymer comprising repeat units of formula (II) or a salt thereof: 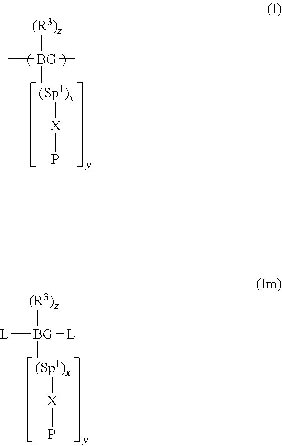
wherein BG is a backbone group; Sp¹ and Sp² are each a spacer group; x is 0 or 1; y is at least 1; X is O or NR² wherein R² is H or a substituent; P is selected from the group consisting of unsubstituted or substituted benzyl, CR¹₃, COR¹, COOR¹ or, if X═O, SiR¹₃; wherein R¹ in each occurrence is a C₁₋₂₀ hydrocarbyl group; R³ in each occurrence is a substituent; z is 0 or a positive integer; and each L is independently a leaving group.

2. A method according to claim 1 wherein each L is independently selected from the group consisting of boronic acid; boronic ester; sulfonic acid; sulfonic ester; and halogen.

3. (canceled)

4. (canceled)

5. (canceled)

6. (canceled)

7. A method according to claim 1 wherein the precursor polymer comprises one or more arylene co-repeat units, the or each arylene co-repeat unit being unsubstituted or substituted with one or more substituents.

8. A method according to claim 1 wherein Sp¹ and Sp² are the same.

9. A method according to claim 1 wherein the precursor polymer comprising repeat units of formula (I) is converted to a polymer comprising repeat units of formula (II) by acid treatment.

10. A method of forming an organic electronic device comprising adjacent first and second organic layers, the method comprising the steps of:
converting a precursor polymer comprising repeat units of formula (I) to a polymer comprising repeat units of formula (II) or a salt thereof: 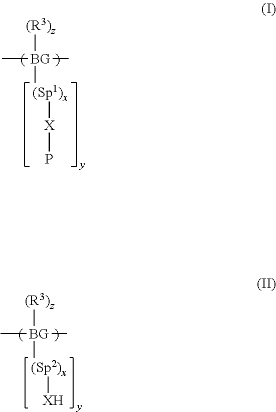
wherein BG is a backbone group; Sp¹ and Sp² are each a spacer group; x is 0 or 1; y is at least 1; X is O or NR² wherein R² is H or a substituent; P is selected from the group consisting of unsubstituted or substituted benzyl, CR¹₃, COR¹, COOR¹ or, if X═O, SiR¹₃;
wherein R¹ in each occurrence is a C₁₋₂₀ hydrocarbyl group; R³ in each occurrence is a substituent; and z is 0 or a positive integer;
forming the first organic layer by depositing a first solution comprising one or more materials dissolved in a non-polar solvent; and
forming the second organic layer by depositing a second solution comprising the polymer comprising repeat units of formula (II) dissolved in a polar solvent.

11. A method according to claim 10 wherein BG is an at least partially conjugated group that is directly conjugated to adjacent repeat units.

12. A method according to claim 11 wherein BG is a C₆₋₂₀ arylene group.

13. A method according to claim 12 wherein BG is fluorene.

14. A method according to claim 10 wherein the repeat units of formula (I) form 5-80 mol % of the repeat units of the precursor polymer.

15. A method according to claim 10 wherein the precursor polymer comprises one or more arylene co-repeat units, the or each arylene co-repeat unit being unsubstituted or substituted with one or more substituents.

16. A method according to claim 10 wherein the second solution comprises a dopant capable of doping the polymer.

17. A method according to claim 16 wherein the dopant comprises a benzimidazole group.

18. A method according to claim 16 wherein the dopant is mixed with the polymer comprising repeat units of formula (II).

19. A method according to claim 16 wherein the dopant is a substituent of a repeat unit of the polymer comprising repeat units of formula (II).

20. A method according to claim 10 wherein the precursor polymer is formed by a metal-catalysed polymerisation.

21. A method according to claim 10 wherein the precursor polymer is formed by polymerising a monomer of formula (Im): 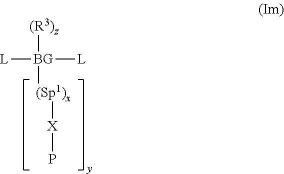
wherein BG is a backbone group; Sp¹ is a spacer group; x is 0 or 1; y is at least 1; X is O or NR² wherein R² is H or a substituent; P is selected from the group consisting of unsubstituted or substituted benzyl, CR¹₃, COR¹, COOR¹ or, if X═O, SiR¹₃; wherein R¹ in each occurrence is a C₁₋₂₀ hydrocarbyl group; R³ in each occurrence is a substituent; z is 0 or a positive integer; and each L is independently a leaving group.

22. A method according to claim 21 wherein each L is independently selected from the group consisting of boronic acid; boronic ester; sulfonic acid; sulfonic ester; and halogen.

23. A method according to claim 10 wherein the organic electronic device is an organic light-emitting device comprising the first and second organic layers disposed between an anode and a cathode.

24. A method according to claim 23 wherein the first organic layer is a light-emitting layer and the second organic layer is an electron-transporting layer or an electron injecting layer.
